(19) United States
(12) Patent Application Publication
(10) Pub. No.: US 2026/0246377 A1
(43) Pub. Date: Aug. 20, 2026

(54) A Programmable Gate Driver Array for a Switched-Capacitor DC-DC Converter

(71) Applicant: Skycore ApS, Copenhagen Ø (DK)

(72) Inventors: Dennis Øland Larsen, København Ø (DK); Pere Llimós Muntal, København Ø (DK); Thomas Pierre Marie Souvignet, København Ø (DK); Guifré Vendrell Pausas, København Ø (DK)

(21) Appl. No.: 18/995,298

(22) PCT Filed: Jul. 4, 2023
(86) PCT No.: PCT/EP2023/068354

§ 371 Date: Jan. 16, 2025

(30) Foreign Application Priority Data
Jul. 19, 2022 (EP) 22185692.5

(51) Int. Cl. H02M 3/07; H02M 1/088; H02M 1/44; H02M 3/157; H02M 3/158; H03K 7/08; H03K 17/284

(52) U.S. Cl. CPC H02M 3/07; H02M 1/088; H02M 1/44; H02M 3/157; H03K 7/08; H03K 17/284; H02M 3/158

(57) ABSTRACT

The invention regards a programmable gate driver array for a switched-capacitor DC-DC converter comprising at least one input terminal, a plurality of power switch terminals connectable to a plurality of power switches configured to convert a DC input voltage from the at least one input terminal to a DC output voltage by a switched-capacitor DC-DC conversion, a plurality of gate drivers configured to drive the plurality of power switch terminals and a clock controller unit, wherein the clock controller unit is configured for performing an individual clock control of the plurality of gate drivers. A switched-capacitor DC-DC converter comprising a programmable gate driver array for a switched-capacitor DC-DC converter and a method for performing an individual clock control of a programmable gate driver array for a switched-capacitor DC-DC converter.

The present disclosure relates to a programmable gate driver array for switched-capacitor DC-DC converter with individual clock control.

### BACKGROUND

In a typical switched-capacitor DC-DC converter, a dead time is needed during switching in order to avoid large current flowing in the switches, also called shoot-through. Indeed, in the case of a simple charge pump, it can occur that while the upper switch closes, the lower switch is not totally opened. This would then create a short between the supply and the ground of the charge pump. In order to avoid this situation, a control circuit is provided to prevent the switches on the two sides, i.e. high and low sides, from turning on simultaneously, that is, both sides are turned off before turning on the appropriate switch. The control circuit introduces what is commonly called a dead time.

Some characteristics of this dead time are very critical for the charge pump, or more generally for the switched-capacitor DC-DC converter. The dead time cannot be too short, because the risk of creating a short between the supply and the ground of the switched-capacitor DC-DC converter would be relatively too high. On the contrary, the dead time can neither be too long, because this leads to higher power loss due to higher flying capacitor ripple voltage and consequently higher conduction losses in the switches due to the accompanying higher RMS current.

The current architectures of switched-capacitor DC-DC converter are based on a dead time being global, which means that the dead time can be adjusted in a clock controller unit but it remains the same for all the switches used in a switched-capacitor DC-DC converter. Thus, some drawbacks can arise such as an increase of the parasitic charge loss and higher electromagnetic interference (EMI). Indeed, in a same switching phase, the switches do not turn on or off simultaneously due to the variations in the propagation and transition delays in digital circuits, level shifters and gate drivers. It is in this critical time period that the parasitic capacitances can be charged and/or discharged through the switch, or switches, which closes first.

It would be beneficial to be able to provide an efficient switched-capacitor DC-DC converter in which the parasitic charge loss can be reduced.

### SUMMARY

The present disclosure relates to a programmable gate driver array for switched-capacitor DC-DC converter comprising at least one input terminal, a plurality of power switch terminals connectable to a plurality of power switches configured to convert a DC input voltage from the at least one input terminal to a DC output voltage by a switched-capacitor power conversion, a plurality of gate drivers configured to drive the plurality of power switch terminals, and a clock controller unit, wherein the clock controller unit is configured for performing an individual clock control of the plurality of gate drivers, wherein the clock controller unit generates individual clock signals to the gate drivers, and wherein the clock controller is further configured to generate individual edge delays on the individual clock signals.

By providing a clock controller unit configured for performing an individual clock control of the plurality of gate drivers, the plurality of power switch terminals can then control a plurality of power switches with independent clock signals, therefore being able to reduce the parasitic charge losses of a switched-capacitor DC-DC converter.

The disclosure further relates to a switched-capacitor DC-DC converter comprising a programmable gate driver array for a switched-capacitor DC-DC converter such as the one previously disclosed, a plurality of flying capacitors connected to the plurality of flying capacitor terminals, and a plurality of power switches connected to the plurality of power switch terminals, wherein the programmable gate driver array is arranged with the plurality of flying capacitors and the plurality of power switches to perform a switched-capacitor DC-DC conversion with an individual clock control of the plurality of power switches.

The switched-capacitor DC-DC converter has several parasitic elements inherent to its design and implementation such as parasitic resistances, capacitances or inductances. These parasitic elements decrease the efficiency of the switched-capacitor DC-DC converter, especially at high switching frequencies. Nevertheless, it is possible to enhance the performance and the efficiency of the switched-capacitor DC-DC converter by independently controlling the plurality of power switches with an individual clock control for each of the plurality of power switches connected to the plurality of power switch terminals.

A method for performing an individual clock control of a programmable gate driver array for a switched-capacitor DC-DC converter is also disclosed, the method comprising the steps of providing a programmable gate driver array for switched-capacitor DC-DC converter comprising at least one input terminal, a plurality of power switch terminals connectable to a plurality of power switches configured to convert a DC input voltage from the at least one input terminal to a DC output voltage by a switched-capacitor DC-DC conversion, a plurality of gate drivers configured to drive the plurality of power switch terminals, a clock controller unit, wherein the clock controller unit is configured for generating individual clock signals to the gate drivers, and wherein the clock controller is further configured to generate individual edge delays on the individual clock signals, and performing the individual clock control of the programmable gate driver array for a switched-capacitor DC-DC converter by using the clock controller unit.

### DESCRIPTION OF THE DRAWINGS

In the following, embodiments and examples will be described in greater detail with reference to the accompanying drawings. The drawings are examples of embodiments and not limiting to the presently disclosed programmable gate driver array for switched-capacitor DC-DC converter.

FIG. 1A shows a schematic view of an embodiment of a programmable gate driver array for switched-capacitor DC-DC converter.

FIG. 1B shows a schematic view of an embodiment of a programmable gate driver array for switched-capacitor DC-DC converter comprising a plurality of power switches where the power switches are segmented switches. FIG. 2 shows a schematic view of an embodiment of the clock controller unit.

FIG. 3A-B show an embodiment of a clock generation scheme for a single inductor hybrid switched-capacitor DC-DC converter topology.

FIG. 4A-D show schematic views of an embodiment of a single inductor hybrid switched-capacitor DC-DC converter topology and some associated clock generation scheme for different switching phases.

FIG. 5A-C show schematic views of an embodiment of a two-phase Dickson switched-capacitor DC-DC converter topology with segmented power switches and some associated clock generation scheme.

FIG. 6A-D show schematic views of an embodiment of a single inductor hybrid switched-capacitor DC-DC converter topology with an external switch and some associated clock generation scheme for different switching phases.

FIG. 7A-B show a schematic view of an embodiment of a two-phase Dickson switched-capacitor DC-DC converter topology and an associated clock generation scheme for parasitic charge recycling.

FIG. 8 shows a flow-chart of the presently disclosed method of performing an individual clock control of a programmable gate driver array for switched-capacitor DC-DC converter.

### DETAILED DESCRIPTION

The present disclosure relates to a programmable gate driver array for a switched-capacitor DC-DC converter comprising a plurality of gate drivers configured to drive a plurality of power switch terminals. The programmable gate driver array further comprises a clock controller unit that may be configured for performing an individual clock control of the plurality of gate drivers. The programmable gate driver array for a switched-capacitor DC-DC converter comprising a plurality of gate drivers shall be construed as comprising a minimum of two gate drivers. In other embodiments, the programmable gate driver array may comprise at least 3, at least 4, or at least 8 gate drivers. As a person skilled in the art will realize, a programmable gate driver array comprising, for example, two gate drivers, wherein the clock controller is configured for performing an individual clock control of the two gate drivers, shall be construed to fall under the above language, even if further gate drivers are added, which do not have individual clock control.

The programmable gate driver array for a switched-capacitor DC-DC converter, and/or the switched-capacitor DC-DC converter, and/or a system comprising the programmable gate driver array or switched-capacitor DC-DC converter may comprise a processing unit for programming and/or controlling the programmable gate driver array and/or its operations. The processing unit may be, for example, a microcontroller or any other microcomputer or processing unit that is suitable for the purpose.

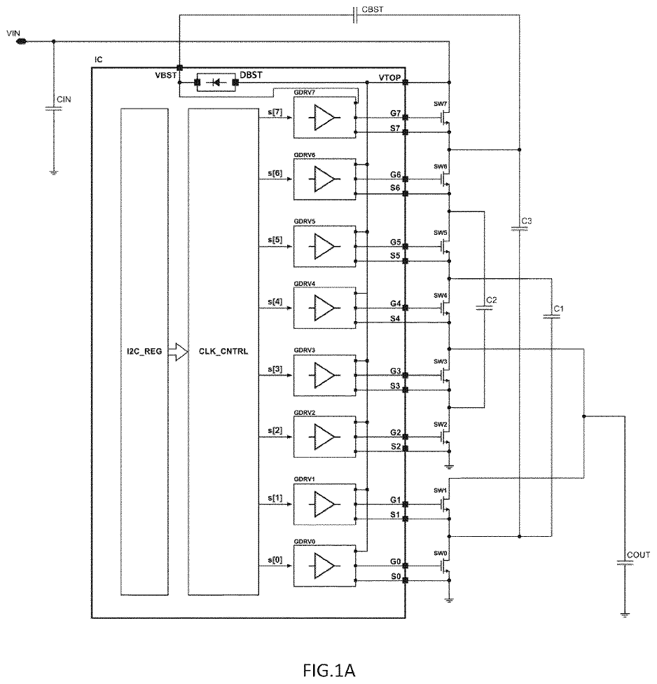

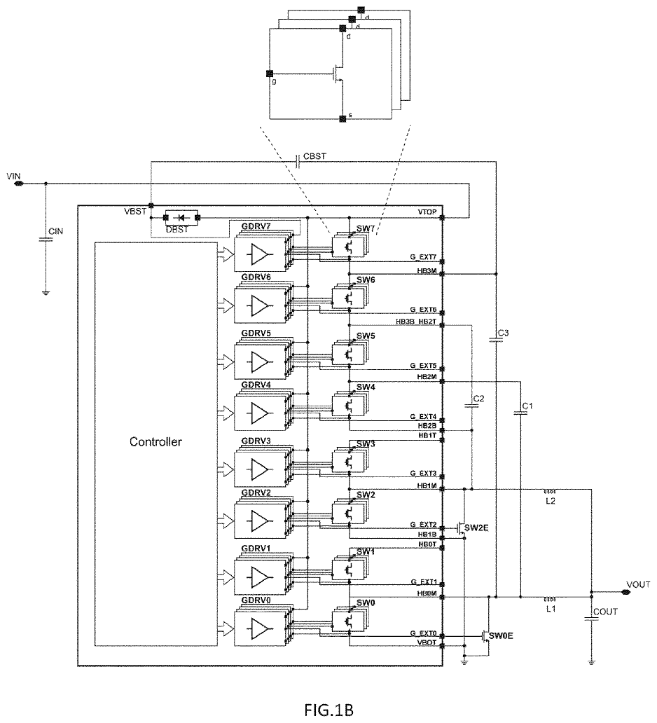

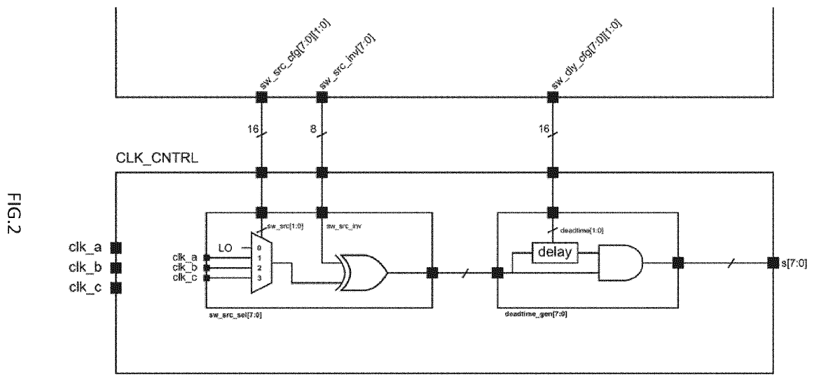

FIG. 1A shows a schematic view of an embodiment of a programmable gate driver array for a switched-capacitor DC-DC converter. The programmable gate driver array comprises at least one input terminal, a plurality of gate drivers configured to drive a plurality of power switch terminals, a plurality of power switch terminals connected to a plurality of power switches that may be configured to convert a DC input voltage from the at least one input terminal to a DC output voltage by a switched-capacitor power conversion, and a clock controller unit. The programmable gate driver array comprises a clock controller CLK_CNTRL. The at least one input terminal is named VIN, which corresponds to the DC input voltage of the programmable gate driver array for switched-capacitor DC-DC converter. The programmable gate driver array comprises a plurality of gate drivers GDRV0-GDRV7, which are configured to independently drive the power switch terminals, namely G0-G7 and S0-S7. The plurality of gate drivers are supplied from VTOP terminal, and GDRV7 is supplied from VBST terminal. A plurality of power switches SW0-SW7 is arranged on the outside of the programmable gate array and connected to the plurality of power switch terminals. A plurality of flying capacitors, namely C1, C2 and C3, are connected together with the plurality of power switches to perform a switched-capacitor DC-DC conversion. The clock controller unit delivers signals s[0]-s[7] to the plurality of gate drivers. A bootstrap circuit is implemented to provide a boosted voltage for the top-most gate driver GDRV7. The bootstrap circuit comprises a bootstrap capacitor CBST, and a bootstrap diode DBST. The top-most gate driver, GDRV7, may require a positive supply voltage, which cannot be provided by connecting the GDRV7 positive supply terminal to VTOP and the GDRV7 negative supply terminal to the source terminal of SW7 as the voltage from VTOP to the source of SW7 is approximately zero when SW7 is conducting. The bootstrap diode may provide a charging path from VTOP to the CBST boost capacitor when SW7 is opened (OFF) and the diode is blocking when SW7 is closed (ON). The result of the bootstrap circuit operation is a stable supply voltage for GDRV7 relative to the GDRV7 negative supply terminal, which is connected to the source terminal of SW7. A decoupling capacitor COUT filters the DC output voltage of the switched-capacitor DC-DC converter and a decoupling capacitor CIN is connected to the at least one input terminal to filter the DC input voltage of the switched-capacitor DC-DC converter.

FIG. 1B shows a schematic view of an embodiment of one of the plurality of power switches. Each of the plurality of power switches (SW0, SW1, SW2, SW3, SW4. SW5, SW6, SW7) has three switch-segments, connected in parallel. The three switch-segments have 3 terminals, namely “g”, “s” and “d”. “g” may stand for “gate”, “d” can stand for “drain” while “s” may potentially stand for “source”. The three switch-segments may preferably be connected in parallel. This means that the “d” terminals of all the switch-segments of a switch may be connected together, and that the “s” terminals of all the switch-segments of a switch may be connected together. The “g” terminals may be individually controlled by different gate drivers. As can be seen, the plurality of power switches may be connected in various suitable ways. For example, SW6 and SW7 are connected in series in the example of FIG. 1B.

The clock controller unit may be configured to perform an individual clock control of the plurality of gate drivers. Any clock signals coming from the clock controller unit may be configured with different frequencies, phases and/or edge delays in order to counteract the effects of any parasitic elements such as parasitic capacitances, resistances and/or inductances of a switched-capacitor DC-DC converter. These parasitic elements are inherent to the design and implementation of a switched-capacitor DC-DC converter, and thus it may be beneficial to potentially have a variety of clock signals to remove the undesirable effects, affecting performance and efficiency.

In order to perform a switched-capacitor DC-DC conversion, the programmable gate driver array may need to deliver a signal to the plurality of power switches terminals with a specific characteristics, depending on the DC-DC conversion desired. In this context, the plurality of power switch terminals may be independently controlled by the plurality of gate drivers. Each of the plurality of gate drivers can output a signal having different characteristics and/or properties to their respective power switch terminals.

The individual clock control can be configured for selecting an individual clock signal from a plurality of clock signal, said individual clock signal having a clock frequency, a clock duty cycle and/or a clock edge delay.

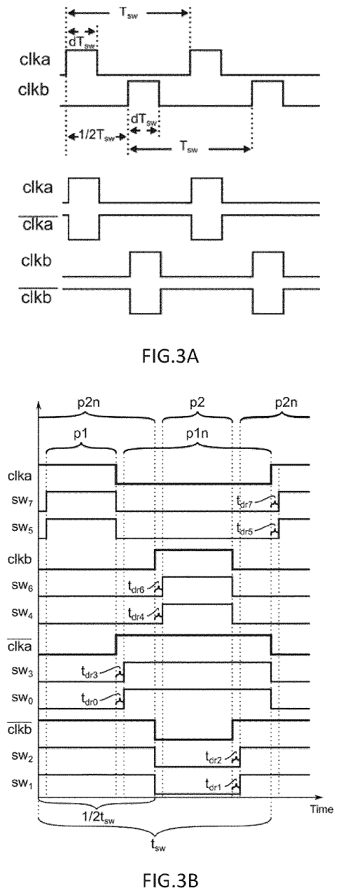

The individual clock signal may be a digital clock signal, oscillating between a low and a high state. The low and the high state of the clock digital signal may generally be defined as a voltage, where the low state has a voltage lower than the high state. FIG. 3A shows an example of a clock signal possibly generated by a clock generator. In this specific example, two digital clock signals are generated, clka and clkb, with clkb having a 180-degrees phase shift compared to clka. Both clka and clkb may be generated by the clock generator, while c̅l̅k̅a̅ and c̅l̅k̅b̅ can be generated by a clock controller. The clock controller may generate at least one secondary clock signal based on the clock signals received from the clock generator.

The clock frequency of the individual clock signal may be a frequency between 1 Hz and 10 MHz, preferably between 50 kHz and 5 MHz. Generally, it may be necessary to have a clock frequency as low as possible, e.g. in a standby mode, where the output voltage may be maintained but where the power dissipation can be minimized. In a standby mode, the gate drivers can still require supply current so continuous balancing of the flying capacitors may be necessary. However, the supply current of the gate drivers can be so low so that a very low clock frequency can be used. More generally, it can be desirable to have a high operating frequency to minimize the size of the required passive components. A higher switching frequency can yield a lower flying capacitor ripple, which may allow for using smaller capacitance value of the flying capacitors. Even more generally, it may be desirable to have a high switching frequency to avoid switching in some ranges of the frequency spectrum where other EMI victims in the surrounding system may be sensitive. E.g. in an automotive system it may be desirable to use a switching frequency at or above 2.2 MHz to avoid the AM radio band. The clock controller unit may further comprise at least one clock switch unit and at least one edge delay controller unit. The at least one clock switch unit may be configured to select a clock from a plurality of clock signals available. The at least one edge delay controller unit can be configured to generate an edge delay on an individual clock signal. This edge delay can be individually configured to deliver a plurality of different clock signals to the plurality of gate drivers to optimize parasitic charge losses in a switched-capacitor DC-DC converter.

An edge delay may be a delay in either a rising edge or a falling edge or both, of a digital clock signal. An edge delay can correct duty cycle distortion by adjusting the edge of the digital clock signal independently of the duty cycle of a digital clock signal. The duty cycle distortion may be due to nonlinearities in components, impendance mismatches, capacitive or inductive loading, signal propagation delays, crosstalk, or power supply noise. By having an individual edge delay control, the different clock signals that may be delivered to the plurality of gate drivers can optimize the driving signals of the plurality of the power switches of the switched-capacitor DC-DC converter. This may be useful for several reasons. For example, in an embodiment of a DC-DC converter topology having a plurality of segmented power switches, individual edge delay control is useful since the switch-segments can be used for charge recycling and to reduce the electromagnetic interferences caused by the switching.

Moreover, in a capacitor DC-DC converter topology where there are parasitic capacitances, the charging and discharging of the parasitic capacitances may give rise to undesired parasitic losses. The parasitic capacitors can be charged and discharged through different loops, depending on which power switches are closed or opened. By controlling edge delays of the power switches in such an embodiment, the parasitic losses can be reduced. programmable gate driver array for a switched-capacitor DC-DC converter may also be configured to recycle parasitic losses by individual edge control.

FIG. 2 shows a schematic view of an embodiment of the clock controller unit. The clock controller unit, namely CLK_CNTRL, comprises a clock switch sw_src_sel and an edge delay controller unit deadtime_gen. The clock controller unit has three input terminals, clk_a, clk_b and clk_c being potentially three different clock signals. These three different clock signals can have different frequencies, different duty cycles, as well as different phases. They may be generated from an internal clock generator, further comprised in the clock controller unit, or they can be provided from one of the at least one input terminal, and potentially be generated outside from the programmable gate driver array for switched-capacitor DC-DC converter. The clock controller unit has one output terminal s[7:0], which consists of 8 different clock signals. The clock controller unit further comprises digital input terminals sw_src_cfg[7:0][1:0], sw_src_inv[7:0] and sw_dly_cfg[7:0][1:0] where these signals may aim at controlling the clock controller unit features. The clock switch comprises a multiplexer and a XOR gate. The multiplexer and the XOR gate are controlled by the digital control signals, namely sw_src_cfg[7:0][1:0] and sw_src_inv[7:0]. The edge delay controller unit comprises a delay unit and an AND gate. The delay unit is controlled by the digital control signals sw_dly_cfg[7:0][1:0].

The clock controller unit may further comprise at least one clock input terminal and at least one clock output terminal. The at least one clock output terminal can be connectable to each of the plurality of gate drivers. As shown in the example of FIG. 2, the at least one clock output terminal s[7:0], which may deliver at least one individual clock signal can be connected to each of the plurality of gate drivers. The at least one clock input terminal may be connected to a clock generator. The clock generator can be a voltage controlled oscillator or a ring oscillator. It can be either integrated on the same chipset as the programmable gate driver array for switched-capacitor DC-DC converter, or it can be integrated on an external device and then potentially provided to the programmable gate driver array clock controller unit through one of the at least one input terminal. A voltage controlled oscillator is an electronic oscillator whose oscillation frequency is controlled by a voltage input. The applied input voltage determines the instantaneous oscillation frequency. A ring oscillator is a device composed of an odd number of NOT gates in a ring, whose output oscillates between two voltage levels. A ring oscillator is a type of voltage controlled oscillator. The NOT gates, or inverters, are attached in a chain and output of the last inverter is fed back into the first. This potentially creates an instability therefore making oscillations to occur. Another type of voltage controlled oscillator is a LC-oscillator. LC oscillators are generally widely used as voltage-controlled oscillators because they can provide much less phase noise than ring oscillators, which is critical for good sensitivity and selectivity in a transceiver. LC oscillators are extremely useful for high frequencies, generally higher than 1 GHz, where phase noise becomes critical. On the other side, they are generally much more bulky than the ring oscillators, since they require a relatively large integrated inductor.

The clock generator may further comprise a phase-lock loop (PLL) and/or a clock divider. A PLL is a control system that generates an output signal whose phase is related to the phase of an input signal. They may comprise multiple elements such as a phase detector, a low-pass filter and a feedback path and/or an optional divider. The PLL may be used for a multiple number of reasons: jitter and noise reduction, frequency synthesis, clock recovery or clock generation. The PLL can be one of its several variations, such as an analog or linear PLL (APLL), a digital PLL (DPLL) or a charge-pump PLL (CP-PLL). Each of these variations may have advantages and/or inconvenient, such as size, complexity or frequency ranges. The choice of one of the PLL variation may be depending on the application desired and/or required. The clock divider is a circuit that takes an input signal of a frequency fin, and generates an output signal of a frequency fout, wherein fout=fin/N, and where N is an integer. A clock divider may be a cheap and quick solution to provide multiple number of clock signals with different frequencies coming from a single clock signal.

The clock controller unit may comprise a plurality of input digital terminals connected from a digital register block. As shown in FIG. 2, the digital control signals such as sw_src_cfg or sw_src_inv are connected to the input digital terminals of the clock controller unit and may be provided by a digital register block. The digital control signals can be connected to the at least one clock switch unit and/or the at least one edge delay controller unit. As shown in FIG. 2, the digital control signal sw_src_inv is connected to the clock switch unit and sw_dly_cfg is connected to the edge delay controller unit. The digital register block can have a serial communication interface with a system or user.

The serial communication interface may be a serial communication bus such as an inter-integrated circuits (12C) serial bus protocol, a serial peripheral interface (SPI) serial bus protocol, system management bus (SMBus), power management bus (PMBus), adaptive voltage scaling bus (AVSBus) or a USB protocol. With a serial communication bus, data bits are transmitted one at a time in a sequential manner over the data bus or communication channel. Parallel communication may also be used, such as Small Computer System Interface (SCSI) or Peripheral Component Interconnect (PCI). Serial communication is generally preferred because of the multiple drawbacks inherent to the architecture of the parallel communication, such as crosstalk, number of cables used or possible clock skews.

The at least one clock switch unit may comprise a multiplexer and a XOR gate. As shown in FIG. 2, the XOR gate can be configured for providing a 180 degree phase shift to the individual clock signal coming from the multiplexer by effectively inverting the clock signal. A 180 degree phase shift may also be configured by using other types of logic gates configuration. The XOR gate can present the benefit of providing a 180 degree phase shift thanks to a unique control signal consisting of one bit. If the unique control signal is set to a low digital state, then the individual clock signal is outputted from the XOR gate with no phase shift. If the unique control signal is set to a high digital state, then the individual clock signal is outputted from the XOR gate with a 180 degree phase shift.

The at least one edge delay controller may further comprise a delay unit and an AND gate, wherein the delay unit and the AND gate can be configured to implement an edge delay to the individual clock signal. FIG. 3B shows an embodiment of a clock generation scheme for a single inductor hybrid switched-capacitor DC-DC converter topology. The generated switching phases p1, p1n, p2 and p2n are all derived from the clock signals clka, clkb, c̅l̅k̅a̅ and c̅l̅k̅b̅, where c̅l̅k̅a̅ and c̅l̅k̅b̅ are the inverse of clka and clkb, respectively, and as shown in FIG. 3A. Some edge delays are shown, such as tdr1, which is an edge delay from the falling edge of clkb, corresponding to the rising edge of c̅l̅k̅b̅, to the rising edge of the sw1 signal, the sw1 signal being individually configured to have the shape of the p2n switching phase. Tdr2 is an edge delay from the falling edge of clkb, corresponding to the rising edge of c̅l̅k̅b̅, to the rising edge of the sw2 clock signal, the sw2 clock signal being individually configured to have the shape of the p2n switching phase. Tdr4 is an edge delay from the rising edge of clkb to the rising edge of the sw4 clock signal, the sw4 clock signal being individually configured to have the shape of the p2 switching phase. All edge delays, namely tdr0-tdr7 can be independently generated.

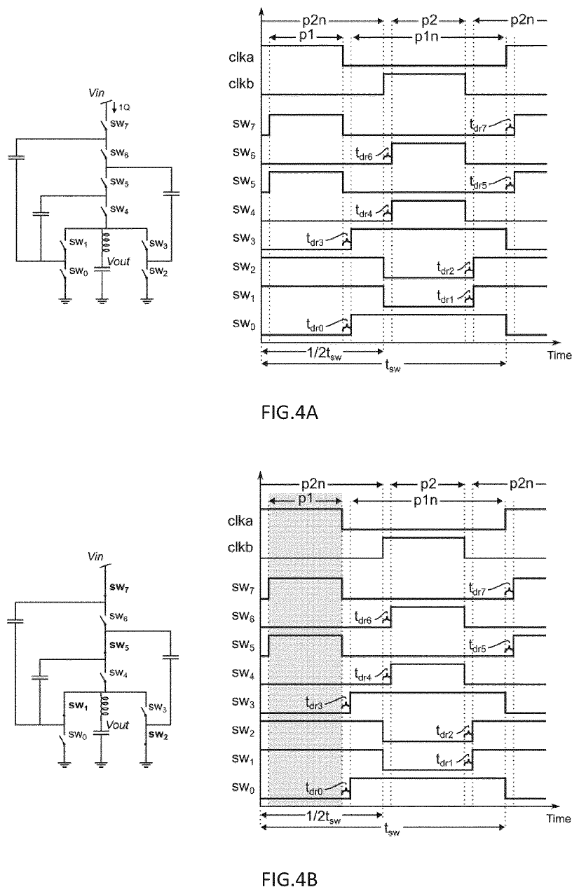

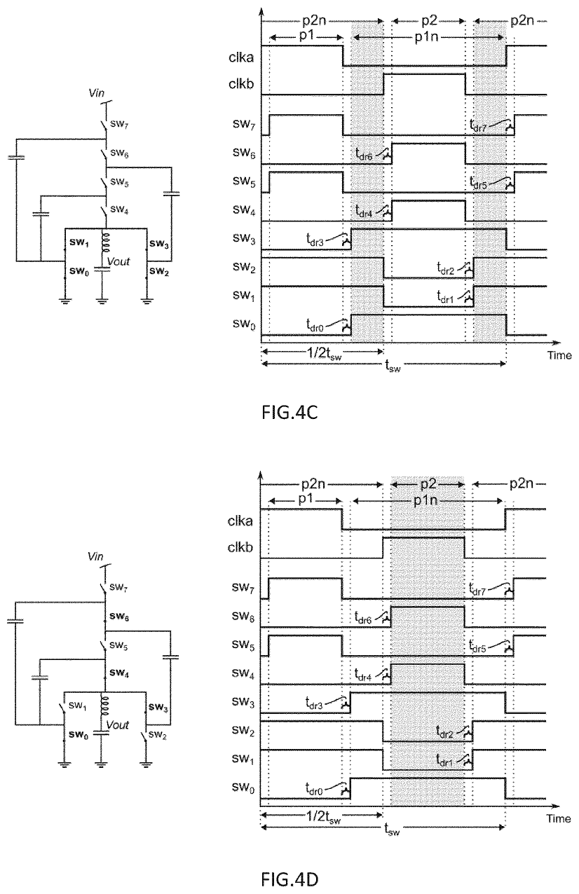

FIG. 4A-D show schematic views of an embodiment of a single inductor hybrid switched-capacitor DC-DC converter topology and some associated clock generation scheme for different switching phases. FIG. 4A shows a schematic view of an embodiment of a single inductor hybrid topology and an associated clock generation scheme. The power switches sw0-sw7 are controlled by different clock signals. As it is shown in FIG. 4A, the duty cycle of the switching phases p1 and p2 is different than the duty cycle of p1n and p2n. Some clock edge delays are implemented between p1 and pin, as well as between p2 and p2n, namely tdr0-tdr7. tdr1, tdr2, tdr4 and tdr6 are implemented to avoid having a potential risk of p2 being in the same state than p2n. tdr0, tdr3, tdr5 and tdr7 are implemented to avoid having a potential risk of p1 being in the same state than p1n. FIG. 4B-D show schematic views of an embodiment of a single inductor hybrid switched-capacitor DC-DC converter topology being in different switching states. The associated diagrams with the different clock signals show which power switches are closed and which ones are not. FIG. 4B shows a switching state when the switching phases p1 and p2n are closed while the others are opened. FIG. 4C shows a switching state when the switching phases pin and p2n are closed while the others are opened. FIG. 4D shows a switching state when the switching phases pin and p2 are closed while the others are opened.

The edge delay can be either a rising edge delay and/or a falling edge delay. The edge delay may be between 0% and 25% of an individual clock signal period, preferably between 0% and 5% of an individual clock signal period. The individual clock signal period is a period of the individual clock signal.

The programmable gate driver array for switched-capacitor DC-DC converter can have a DC input voltage being between 12 and 400 V, preferably between 36 and 60 V. It can be configured for stepped-up and stepped-down DC-DC conversions, wherein the DC input voltage can be lower or higher than the DC output voltage, with many possible DC-DC conversion ratio, depending on the programmable gate driver array configuration. The architecture of the plurality of gate drivers may allow a system or a user to use a large range of DC input voltage.

In another aspect, a switched-capacitor DC-DC converter is disclosed. The switched-capacitor DC-DC converter may comprise a programmable gate driver array for switched-capacitor DC-DC converter as previously described, a plurality of flying capacitors connected to the plurality of flying capacitor terminals and a plurality of power switches connected to the plurality of power switch terminals. The programmable gate driver array can be arranged with the plurality of flying capacitors and the plurality of power switches to perform a switched-capacitor DC-DC conversion with an individual control of the plurality of power switches.

The plurality of power switches and the plurality of flying capacitors can be configured to perform a variety of power conversion such as a Dickson-type power conversion, such as Dickson 1/4 or a Dickson 1/6. Other variants of power conversion can also be performed such as a Ladder 1/3, a Divider 1/2 or a Ladder 1/5. The plurality of power switches and the plurality of flying capacitors can also be configured in a Single Inductor Hybrid Converter (SIHC) configuration. As shown in FIG. 4A, one inductor is connected to the flying capacitors through the switches sw1, sw3 and sw4. This enables a hybrid configuration of a switched-capacitor DC-DC converter. This hybrid configuration may add some benefits to a switched-capacitor DC-DC converter without inductors. Hybrid switched-capacitor converters can be categorized as resonant or soft-charged depending on where the at least one inductor is placed. Adding the at least one inductor in series with the plurality of flying capacitors creates a resonant topology. Adding the at least one inductor with an inductor terminal connected to a converter input, output, ground/reference terminal, or an intermediate DC bus, creates a soft-charged converter. In a resonant switched-capacitor DC-DC converter, an inductor is added in series with at least one flying capacitor to create a resonant LC tank that has a low impedance at a given resonant frequency. The inductor will have zero DC current as it is connected in series with one or more capacitors. This resonant configuration allows for using smaller capacitors in conjunction with one or more inductors.

Depending on the available capacitor and inductor technologies for implementing the converter's passive components, it might in some cases be beneficial to use resonant topologies, such as the switched tank converter, to achieve a certain converter performance with a combination of inductors and capacitors instead of only capacitors. Furthermore, resonant switched-capacitor power converters have approximately sinusoidal current and voltage waveforms, which have lower high-frequency spectral energy compared with the approximately square-wave waveforms of switched capacitor power converters without inductors. This can be beneficial in some applications, however this benefit is a tradeoff with the larger radiated magnetic field from the inductor, which is not an issue in switched capacitor power converters without inductors.

In one embodiment, at least one of the plurality of power switches is a segmented switch, comprising a plurality of switch-segments. The segmentation of the plurality of power switches may allow a safe start-up of the switched-capacitor DC-DC converter, by possibly limiting an inrush current, said inrush current due to the presence of multiple low impedance loops in the switched-capacitor DC-DC converter. Secondly, the segmentation of the power switches can allow a system or a user to enable only some of the switch-segments, therefore limiting the power consumption of the switched-capacitor DC-DC converter. Only a few switch-segments may be needed if the output load requires a small current. For instance, in a case where the switched-capacitor DC-DC converter is supplying a CPU, if the CPU is in throttled mode, it does not require as much current as when it may be configured in a normal mode, where more current can be desired.

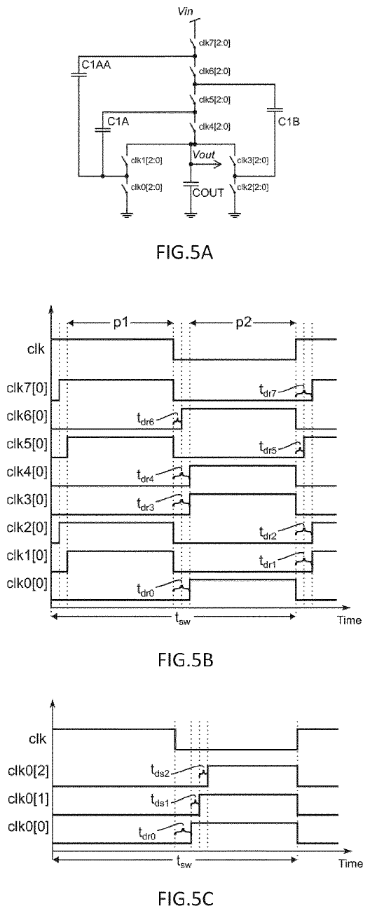

FIG. 5A-C show schematic views of an embodiment of a two-phase Dickson switched-capacitor DC-DC converter topology with segmented power switches and some associated clock generation scheme. FIG. 5A shows a schematic view of an embodiment of a two-phase Dickson switched-capacitor DC-DC converter topology where the eight power switches are segmented. Each power switches comprises three switch-segments, wherein each of the switch-segments are controlled by an individual clock signal. For instance, clk7[2:0] is a bus of 3 independent clock signals. The same applies for the rest of the bus, such as clk6, clk5, clk4, clk3, clk2, clk1 or clk0. FIG. 5B shows a clock generation scheme associated with the first switch segments in each of the 8 power switches shown in FIG. 5A. FIG. 5C shows an example of edge delays between the switch-segments of one of the power switch, namely the power switch controlled by clk0[2:0]. As shown in FIG. 5C, the 3 switch-segments can be enabled at different time, each of the switch-segments having a different edge delay, for example tds1 or tds2, compared to the reference clock signal, namely clk0[0]. In this context, the switch-segments can be used for charge recycling and to reduce the electromagnetic interferences caused by the switching.

The plurality of power switches can be disposed on an external semiconductor die. This external semiconductor die can be manufactured using a semiconductor process optimized for power transistor implementation. These semiconductor processes optimized for power transistor implementation may use a vertical transistor structure, wherein the transistor drain-source terminals are arranged on opposite sides of the transistor die. It may be beneficial for high-voltage power transistor implementation but probably not for advanced analog and digital circuits, preferably designed for low power consumption. Moreover, power transistors may benefit from a possible implementation using high electron mobility materials such as GaN or SIC. Semiconductor processes based on such materials may be not well suited for implementation of p-type transistors, which may be required for implementing digital logic circuits using complementary metal-oxide-semiconductor (CMOS) technology. The external semiconductor die can also be optimized for implementing advanced analog and digital circuitry, such as level-shifters, gate drivers, clock generation circuits, clock controllers, linear voltage regulators or temperature sensors. Semiconductor processes optimized for advanced analog and digital circuitry may require more processing steps and photomasks to implement a wider selection of electronic components. In order to support the possible wider selection of electronic components, tradeoffs must be made in the semiconductor material features that might decrease the performance of power transistors implemented using the same semiconductor process.

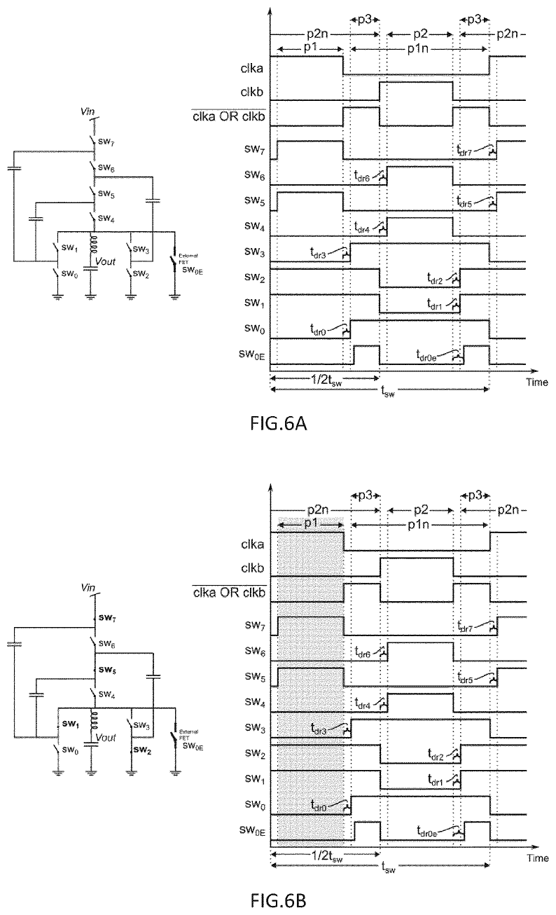

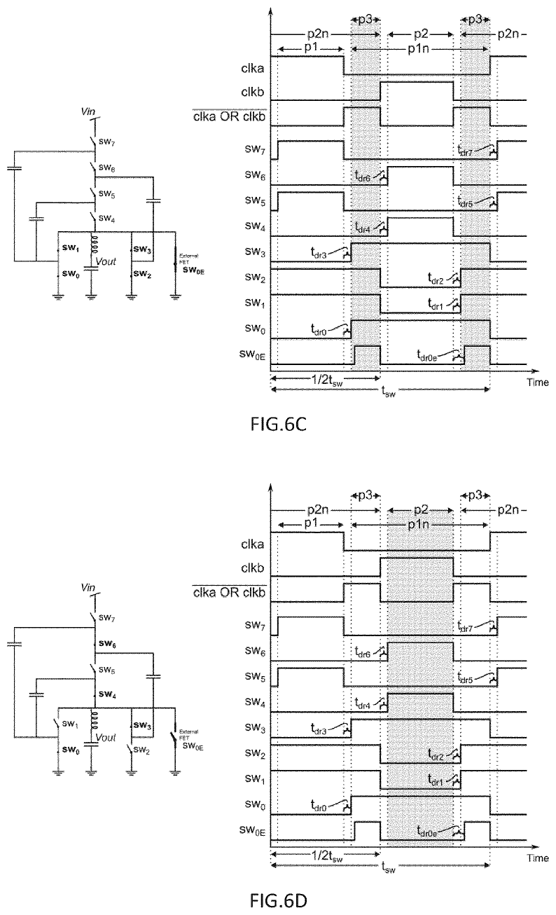

FIG. 6A-D show schematic views of an embodiment of a single inductor hybrid switched-capacitor DC-DC converter topology with an external switch and some associated clock generation scheme for different switching phases. FIG. 6A shows a schematic view of a single inductor hybrid topology with an external switch and an associated clock generation scheme. FIG. 6B shows a schematic view of an embodiment of a single inductor hybrid switched-capacitor DC-DC converter topology where four switches are closed and the rest of the switches are opened. FIG. 6B also shows the associated clock generation scheme where a first switching phase is emphasized in grey. Two clocks are generated, clka and clkb, as well as their inverse, c̅l̅k̅a̅ and c̅l̅k̅b̅. From these four clock signals, all the switch driving signals are generated with different and independent edge delays, namely tdr0-tdr7 and tdr0e. The clock signal controlling the external switch SWOE is generated by a logic combination of clka and clkb, c̅l̅k̅a̅ O̅R̅ c̅l̅k̅b̅ since the frequency of interest is twice the frequency of clka or clkb. In this first switching state, the switches SW1, SW2, SW5 and SW7 are closed while the other switches are opened. FIG. 6C-D show schematic views of an embodiment of a single inductor hybrid topology being in different switching states than in FIG. 6B. FIG. 6C shows a second switching state where the external switch SWOE is closed as well as SW0-SW3 while the other switches are opened. FIG. 6D shows a third switching state where the switches SW0, SW3, SW4 and SW6 are closed while the other switches are opened. FIG. 6B-D show the different switching phases of a single inductor hybrid-switched capacitor DC-DC converter topology comprising an external switch. As it can be seen on the different clock generation schemes, each one of the switches may be independently controlled by a unique clock signal, said unique clock signal being generated from a clock signal and comprising an independent edge delay. In FIG. 6A-D, the rising edge delay tdr0e may be configured to be larger than tdr1 and tdr2 to minimize the dv/dt at the switching node by having SW1 and SW2 closed before the low-impedance SWOE closes.

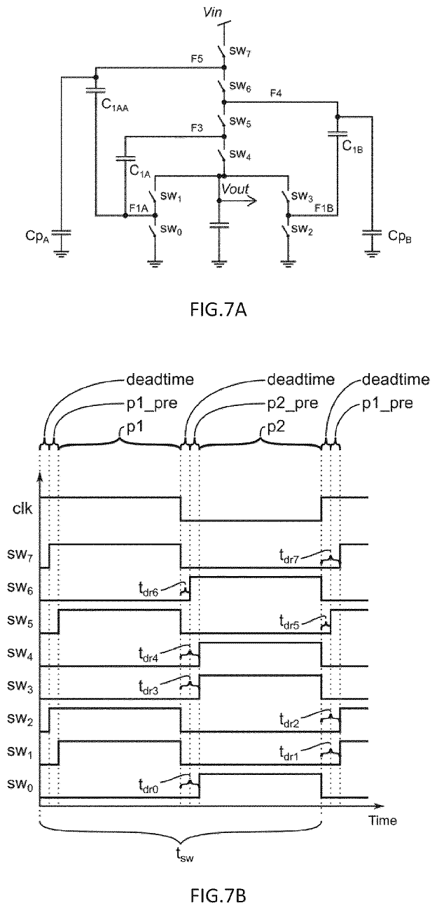

FIG. 7A-B show a schematic view of an embodiment of a two-phase Dickson switched-capacitor DC-DC converter topology and an associated clock generation scheme for parasitic charge recycling. FIG. 7A shows a schematic view of an embodiment of a two-phase Dickson switched-capacitor DC-DC converter topology. It comprises 8 switches, SW0-SW7, three flying capacitors, C1A-C1AA-C1B and two parasitic capacitances CpA and CpB. The two parasitic capacitances may generally be smaller than the flying capacitors. These parasitic capacitances CpA and CpB may be charged and discharged in each switching period of the switched-capacitor DC-DC converter. The charging and discharging of the parasitic capacitances gives rise to undesired parasitic losses. The parasitic capacitors can be charged and discharged through different loops, depending on which power switches are closed or opened. By controlling the timing of each of the plurality of power switches, the parasitic losses can be reduced. A decoupling capacitor is also arranged to filter the DC output voltage Vout. FIG. 7B shows an example of a clock generation scheme for the two-phase Dickson switched-capacitor DC-DC converter topology in order to potentially optimize the efficiency of the switched-capacitor DC-DC converter. A deadtime is implemented by delaying the rising edge of the power switches in a given switching phase in order to give the power switches enough time to fully open or turn OFF. Due to their physical implementation, the power switches controlled by either p1 or p2 may not close or open at the same time. This effect can make the parasitic capacitances to charge and/or discharge through the power switch which closes first, and this power switch may not be the most efficient one in order to recycle the parasitic losses in the best possible way. Therefore, from a clock signal clk, a plurality of clock signals are generated for each of the plurality of power switches shown in FIG. 7A, SW0-SW7. For instance, SW7 is controlled by a clock signal having an edge delay tdr7 after the rising edge of the clock signal clk. SW6 is controlled by a clock signal having an edge delay tdr6 after the falling edge of the clock signal. Each edge delay shown in FIG. 7B can be independently created by the clock controller, and they may potentially be different from each other.

In another aspect, a method for performing an individual clock control of a programmable gate driver array for a switched-capacitor DC-DC converter is disclosed. The method comprises the steps of providing a programmable gate driver array for a switched-capacitor DC-DC converter comprising at least one input terminal, a plurality of power switch terminals connectable to a plurality of power switches configured to convert a DC input voltage from the at least one input terminal to a DC output voltage by a switched-capacitor power conversion, a plurality of gate drivers configured to drive the plurality of power switch terminals, a clock controller unit, wherein the clock controller unit is configured for performing an individual clock control of the plurality of gate drivers; and performing the clock control of the programmable switch array for switched-capacitor DC-DC conversion by using the clock controller unit.

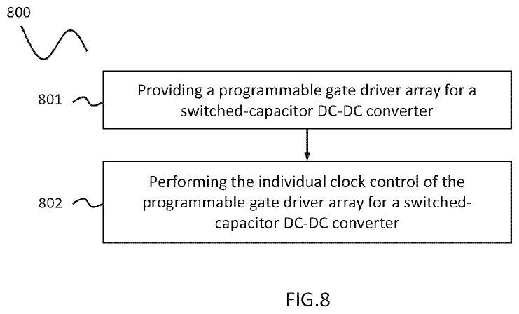

FIG. 8 shows a flow-chart of the presently disclosed method of performing an individual clock control of a programmable gate driver array for a switched-capacitor DC-DC converter (800). The method comprises the following steps, which are providing a programmable gate driver array for a switched-capacitor DC-DC converter (801) and performing the individual clock control of the programmable gate driver array for a switched-capacitor DC-DC converter (802).

### FURTHER DETAILS OF THE INVENTION

1. A programmable gate driver array for a switched-capacitor DC-DC converter comprising:
   at least one input terminal;
   a plurality of power switch terminals connectable to a plurality of power switches configured to convert a DC input voltage from the at least one input terminal to a DC output voltage by a switched-capacitor DC-DC conversion;
   a plurality of gate drivers configured to drive the plurality of power switch terminals; and
   a clock controller unit;
   wherein the clock controller unit is configured for performing an individual
   clock control of the plurality of gate drivers.
2. The programmable gate driver array for a switched-capacitor DC-DC converter according to item 1, wherein the plurality of power switch terminals are independently controlled by the plurality of gate drivers.
3. The programmable gate driver array for a switched-capacitor DC-DC converter according to any one of the preceding items, wherein the individual clock control is configured for selecting an individual clock signal from a plurality of clock signal, said individual clock signal having a clock frequency, a clock duty cycle and/or a clock edge delay.
4. The programmable gate driver array for a switched-capacitor DC-DC converter according to item 3, wherein the individual clock signal is a digital clock signal oscillating between a high and a low state.
5. The programmable gate driver array for a switched-capacitor DC-DC converter according to item 3, wherein the clock frequency is between 1 Hz and 10 MHz, preferably between 50 kHz and 5 MHz.
6. The programmable gate driver array for a switched-capacitor DC-DC converter according to any one of the preceding items, wherein the clock controller unit comprises at least one clock switch unit and at least one edge delay controller unit.
7. The programmable gate driver array for a switched-capacitor DC-DC converter according to any one of the preceding items, wherein the clock controller unit further comprises at least one clock input terminal and at least one clock output terminal connectable to the plurality of gate drivers.
8. The programmable gate driver array for a switched-capacitor DC-DC converter according to item 7, wherein the at least one clock input terminal is connected to a clock generator.
9. The programmable gate driver array for a switched-capacitor DC-DC converter according to item 8, wherein the clock generator is a voltage controlled oscillator or a ring oscillator.
10. The programmable gate driver array for a switched-capacitor DC-DC converter according to any one of items 8 or 9, wherein the clock generator further comprises a phase-lock loop (PLL) and/or a clock divider.
11. The programmable gate driver array for a switched-capacitor DC-DC converter according to any one of the preceding items, wherein the clock controller unit further comprises a plurality of input digital terminals connected from a digital register block to the at least one clock switch unit and/or to the at least one edge delay controller unit.
12. The programmable gate driver array for a switched-capacitor DC-DC converter according to item 11, wherein the digital register block has a serial communication interface.
13. The programmable gate driver array for a switched-capacitor DC-DC converter according to item 12, wherein the serial communication interface is an 12C serial communication bus.
14. The programmable gate driver array for a switched-capacitor DC-DC converter according to any one of the preceding items, wherein the at least one clock switch unit comprises a multiplexer and a XOR gate.
15. The programmable gate driver array for a switched-capacitor DC-DC converter according to item 14, wherein the XOR gate is configured for providing a 180 degrees phase shift to the individual clock signal.
16. The programmable gate driver array for a switched-capacitor DC-DC converter according to any one of the preceding items, wherein the at least one edge delay controller unit further comprises a delay unit and a AND gate, wherein the delay unit and the AND gate are configured to implement an edge delay to the individual clock signal.
17. The programmable gate driver array for a switched-capacitor DC-DC converter according to item 16, wherein the edge delay is a rising edge delay and/or a falling edge delay.
18. The programmable gate driver array for a switched-capacitor DC-DC converter according to any one of the preceding items, wherein the edge delay is between 0% and 25% of an individual clock signal period, preferably between 0% and 5% of an individual clock signal period.
19. The programmable gate driver array for a switched-capacitor DC-DC converter according to any one of the preceding items, wherein the individual clock signal period is a period of the individual clock signal.
20. The programmable gate driver array for a switched-capacitor DC-DC converter according to any one of the preceding items, wherein the DC input voltage is between 12 and 400 V, preferably between 36 and 60 V.
21. A switched-capacitor DC-DC converter comprising:
   a programmable gate driver array for a switched-capacitor DC-DC converter according to items 1-20;
      a plurality of flying capacitors connected to the plurality of flying capacitor terminals; and
      a plurality of power switches connected to the plurality of power switch terminals;
      wherein the programmable gate driver array is arranged with the plurality of flying capacitors and the plurality of power switches to perform a switched-capacitor DC-DC conversion with an individual clock control of the plurality of power switches.
22. The switched-capacitor DC-DC converter according to item 21, wherein the plurality of power switches and the plurality of flying capacitors are configured to perform a DC-DC conversion in a Dickson 1/4 or Ladder 1/5 or Dickson 1/6 configuration.
23. The switched-capacitor DC-DC converter according to any one of items 21 or
22, wherein at least one of the plurality of power switches is a segmented switch, comprising a plurality of switch-segments.
24. The switched-capacitor DC-DC converter according to any one of items 21-23, wherein the plurality of power switches are disposed on an external semiconductor die.
25. A method for performing an individual clock control of a programmable gate driver array for a switched-capacitor DC-DC converter comprising the following steps:
   providing a programmable gate driver array for a switched-capacitor DC-DC converter comprising:
      at least one input terminal;
      a plurality of power switch terminals connectable to a plurality of power switches configured to convert a DC input voltage from the at least one input terminal to a DC output voltage by a switched-capacitor DC-DC conversion;
      a plurality of gate drivers configured to drive the plurality of power switch terminals;
      a clock controller unit, wherein the clock controller unit is configured for performing an individual clock control of the plurality of gate drivers; and
   performing the individual clock control of the programmable gate driver array for a switched-capacitor DC-DC converter by using the clock controller unit.
26. The method for performing an individual clock control of a programmable gate driver array for a switched-capacitor DC-DC converter according to item 25, wherein the programmable gate driver array is the programmable gate driver array for switched-capacitor DC-DC converter according to items 1-20.

1-15. (canceled)

16. A programmable gate driver array for a switched-capacitor DC-DC converter comprising:
at least one input terminal;
a plurality of power switch terminals connectable to a plurality of power switches configured to convert a DC input voltage from the at least one input terminal to a DC output voltage by a switched-capacitor DC-DC conversion;
a plurality of gate drivers configured to drive the plurality of power switch terminals; and
a clock controller unit;
wherein the clock controller unit is configured for performing an individual clock control of the plurality of gate drivers, wherein the clock controller unit generates individual clock signals to the gate drivers, and wherein the clock controller is further configured to generate individual edge delays on the individual clock signals.

17. The programmable gate driver array for a switched-capacitor DC-DC converter of claim 16, wherein the plurality of power switch terminals are independently controlled by the plurality of gate drivers.

18. The programmable gate driver array for a switched-capacitor DC-DC converter of claim 16, wherein the individual clock control is configured for selecting an individual clock signal from a plurality of clock signals, said individual clock signal having a clock frequency, a clock duty cycle and/or a clock edge delay.

19. The programmable gate driver array for a switched-capacitor DC-DC converter of claim 18, wherein the clock frequency is between 1 Hz and 10 MHz.

20. The programmable gate driver array for a switched-capacitor DC-DC converter of claim 19, wherein the clock frequency is between 1 Hz and 10 MHz.

21. The programmable gate driver array for a switched-capacitor DC-DC converter of claim 16, wherein the clock controller unit comprises at least one clock switch unit and at least one edge delay controller unit.

22. The programmable gate driver array for a switched-capacitor DC-DC converter of claim 16, wherein the at least one clock switch unit comprises a multiplexer and a XOR gate.

23. The programmable gate driver array for a switched-capacitor DC-DC converter of claim 22, wherein the XOR gate is configured for providing a 180 degrees phase shift to the individual clock signal.

24. The programmable gate driver array for a switched-capacitor DC-DC converter of claim 16, wherein the at least one edge delay controller unit further comprises a delay unit and a AND gate, wherein the delay unit and the AND gate are configured to implement an edge delay to the individual clock signal.

25. The programmable gate driver array for a switched-capacitor DC-DC converter of claim 24, wherein the edge delay is one or both of a rising edge delay and a falling edge delay and wherein the edge delay is between 0% and 25% of an individual clock signal period.

26. The programmable gate driver array for a switched-capacitor DC-DC converter of claim 25, wherein the edge delay is between 0% and 5% of an individual clock signal period.

27. The programmable gate driver array for a switched-capacitor DC-DC converter of claim 16, wherein the DC input voltage is between 12 and 400 V.

28. The programmable gate driver array for a switched-capacitor DC-DC converter of claim 27, wherein the DC input voltage is between 36 and 60 V.

29. A switched-capacitor DC-DC converter comprising:
a programmable gate driver array for a switched-capacitor DC-DC converter of claim 1;
a plurality of flying capacitors connected to the plurality of flying capacitor terminals; and
a plurality of power switches connected to the plurality of power switch terminals;
wherein the programmable gate driver array is arranged with the plurality of flying capacitors and the plurality of power switches to perform a switched-capacitor DC-DC conversion with an individual clock control of the plurality of power switches.

30. The switched-capacitor DC-DC converter of claim 29, wherein at least one of the plurality of power switches is a segmented switch, comprising a plurality of switch-segments.

31. The switched-capacitor DC-DC converter of claim 29, wherein the plurality of power switches are disposed on an external semiconductor die.

32. A method for performing an individual clock control of a programmable gate driver array for a switched-capacitor DC-DC converter comprising the following steps:
providing a programmable gate driver array for a switched-capacitor DC-DC converter comprising:
at least one input terminal;
a plurality of power switch terminals connectable to a plurality of power switches configured to convert a DC input voltage from the at least one input terminal to a DC output voltage by a switched-capacitor DC-DC conversion;
a plurality of gate drivers configured to drive the plurality of power switch terminals;
a clock controller unit, wherein the clock controller unit is configured for generating individual clock signals to the gate drivers, and wherein the clock controller is further configured to generate individual edge delays on the individual clock signals; and
performing the individual clock control of the programmable gate driver array for a switched-capacitor DC-DC converter by using the clock controller unit.
